(19) United States
(12) Patent Application Publication
(10) Pub. No.: US 2024/0413038 A1
(43) Pub. Date: Dec. 12, 2024

(54) STACKED SEMICONDUCTOR PACKAGE AND LOWER SEMICONDUCTOR PACKAGE USED FOR THE SAME

(71) Applicant: Samsung Electronics Co., Ltd., Suwon-si (KR)

(72) Inventors: Hwanjoo PARK, Suwon-si (KR); Jae Choon KIM, Suwon-si (KR); Sunggu KANG, Suwon-si (KR); Taehwan KIM, Suwon-si (KR)

(73) Assignee: Samsung Electronics Co., Ltd., Suwon-si (KR)

(21) Appl. No.: 18/402,558

(22) Filed: Jan. 2, 2024

(30) Foreign Application Priority Data
Jun. 8, 2023 (KR) 10-2023-0073448

(51) Int. Cl. H01L 23/367; H01L 23/31; H01L 23/498; H01L 23/538; H01L 25/10

(52) U.S. Cl. CPC H01L 23/367; H01L 23/3121; H01L 23/49811; H01L 23/5383; H01L 25/105; H01L 24/16; H01L 24/32; H01L 24/73; H01L 2224/16227; H01L 2224/32225; H01L 2224/73204

(57) ABSTRACT

A stacked semiconductor package includes: a first semiconductor package that includes a first region and a second region and includes a semiconductor chip including a first element at the first region and a second element at the second region; a second semiconductor package on the first region of the first semiconductor package; and a member for heat dissipation at the second region of the first semiconductor package and overlapping at least a portion of the second element in a vertical direction perpendicular to an in-plane direction of the first semiconductor package.

### CROSS-REFERENCE TO RELATED APPLICATION

This application claims priority to and the benefit of Korean Patent Application No. 10-2023-0073448 filed in the Korean Intellectual Property Office on Jun. 8, 2023, the entire contents of which are incorporated herein by reference.

### BACKGROUND

### Field

The present inventive concepts relate to stacked semiconductor packages and lower semiconductor packages used for the same.

### Description of the Related Art

A semiconductor device may be miniaturized and may perform various functions so that the semiconductor device is widely used in various electronic industries. With development of the electronics industry, research is continuing on a fine process technology and a packaging technology that reduce a size of the semiconductor device while increasing performance of the semiconductor device.

A stacked semiconductor package that allows for miniaturization, multi-functionality, and high integration by stacking an upper semiconductor package on a lower semiconductor package has been proposed. In the stacked semiconductor package, heat generated from a semiconductor element or semiconductor elements included in the lower semiconductor package has to be dissipated in a lower or upper direction. However, since the upper semiconductor package is provided at an upper portion of the semiconductor element included in the lower semiconductor package, a heat dissipation property in the upper direction may be deteriorated. The deterioration of the heat dissipation property may become more severe as the semiconductor package becomes more highly integrated.

Accordingly, a structure that effectively improves the heat dissipation property in the stacked semiconductor package may be desired.

### SUMMARY

Some example embodiments provide a stacked semiconductor package capable of improving a heat dissipation property and/or a lower semiconductor package used for the same.

A stacked semiconductor package according to some example embodiments may include a first semiconductor package, a second semiconductor package, and a member for heat dissipation. The first semiconductor package may include a first region and a second region and may further include a semiconductor chip. The semiconductor chip may include a first element at the first region and a second element at the second region. The second semiconductor package may be on the first region of the first semiconductor package. The member for heat dissipation may be at the second region of the first semiconductor package and may overlap at least a portion of the second element in a vertical direction, the vertical direction extending perpendicular to an in-plane direction of the first semiconductor package.

A stacked semiconductor package according to some example embodiments may include a first semiconductor package, a second semiconductor package, and a heat source mark. The first semiconductor package may include a first region and a second region and may further include a semiconductor chip including a first element at the first region and a second element at the second region. The second element may be a higher power element than the first element. The second semiconductor package may be at the first region of the first semiconductor package. The heat source mark may be at the second region to overlap at least a portion of the second element in a vertical direction, the vertical direction extending perpendicular to an in-plane direction of the first semiconductor package.

A lower semiconductor package for a stacked semiconductor package according to some example embodiments may include a semiconductor chip, a first redistribution portion, a second redistribution portion, a mold layer, and a heat source mark. The semiconductor chip may include a first element at a first region and a second element at a second region, wherein the second element is a higher power element than the first element. The first redistribution portion and the second redistribution portion may be respectively on opposite surfaces of the semiconductor chip. The mold layer may surround the semiconductor chip between the first redistribution portion and the second redistribution portion. The heat source mark may be at the second region to overlap at least a portion of the second element in a vertical direction at an outer surface of the second redistribution portion and configured as a bonding member, the vertical direction extending perpendicular to an in-plane direction of the lower semiconductor package.

According to some example embodiments, heat of a semiconductor chip included in a first semiconductor package disposed at a lower portion of a stacked semiconductor package may be effectively radiated to the outside of the stacked semiconductor package. In other words, by disposing a heating element that may generate a relatively large amount of heat and a member for heat dissipation at a second region of the first semiconductor package (e.g., such that the member for heat dissipation overlaps the heating element in a vertical direction extending perpendicular to an in-plane direction of the first semiconductor package), the heat generated from the semiconductor chip may be effectively dissipated to the outside of the stacked semiconductor package, thereby improving heat dissipation efficiency and/or performance of the stacked semiconductor package and thereby improving performance and reliability of the stacked semiconductor package due to the improved heat dissipation efficiency and/or performance. In addition, a space may be efficiently used by disposing a second semiconductor package and/or a through connecting portion (or a penetrating connecting portion) at a first region of the first semiconductor package.

In some example embodiments, a heat source mark may be used as an align mark (or an alignment mark) for aligning the heat dissipation member and/or as a bonding member for bonding the heat dissipation member. Accordingly, the heat dissipation member may be efficiently aligned and bonded using a simple structure, thereby reducing the likelihood of misalignment or misplacement of the heat dissipation member and thereby reducing the likelihood of a manufacturing process defect that could reduce heat dissipation efficiency and/or performance of the stacked semiconductor chip, and thereby improving the reliability of manufactured stacked semiconductor chips.

### BRIEF DESCRIPTION OF THE DRAWINGS

FIG. 1 is a cross-sectional view showing a stacked semiconductor package according to some example embodiments.

FIGS. 2A and 2B are partially enlarged cross-sectional views of region A of FIG. 1, showing various examples of a heat source mark included in the stacked semiconductor package shown in FIG. 1 according to some example embodiments.

FIG. 3 is a plan view showing a first semiconductor package included in the stacked semiconductor package shown in FIG. 1 according to some example embodiments.

FIG. 4 is a plan view showing the stacked semiconductor package shown in FIG. 1 according to some example embodiments.

FIG. 5 is a plan view showing a modified example of the first semiconductor package included in the stacked semiconductor package shown in FIG. 1 according to some example embodiments.

FIG. 6 is a cross-sectional view showing a stacked semiconductor package according to some example embodiments.

FIG. 7 is a cross-sectional view showing a stacked semiconductor package according to some example embodiments.

FIG. 8 is a plan view showing a stacked semiconductor package according to a modified example according to some example embodiments.

FIG. 9 is a plan view showing a stacked semiconductor package according to another modified example according to some example embodiments.

### DETAILED DESCRIPTION

Some example embodiments of the present inventive concepts will be described more fully hereinafter with reference to the accompanying drawings for those skilled in the art to which the present inventive concepts pertain to easily practice the present inventive concepts. The present inventive concepts may be implemented in various different forms and is not limited to the example embodiments provided herein.

A portion unrelated to the description is omitted in order to clearly describe the present inventive concepts, and the same or similar components are denoted by the same reference numeral throughout the present specification.

Further, since sizes and thicknesses of portions, regions, members, units, layers, films, etc. shown in the accompanying drawings may be arbitrarily shown for better understanding and ease of description, the present inventive concepts are not limited to the illustrated sizes and thicknesses. Thicknesses of some portions, regions, members, units, layers, films, etc. may be enlarged in the drawings in order to improve clarity. In addition, in the drawings, thicknesses of portions, regions, members, units, layers, films, etc. may be exaggerated for convenience of explanation.

It will be understood that when a component such as a layer, film, region, or substrate is referred to as being “on” another component, it may be directly on other component or intervening components may also be present. In contrast, when a component is referred to as being “directly on” another component, there are no intervening components present. Further, when a component is referred to as being “on” or “above” a reference component, a component may be positioned on or below the reference component, and does not necessarily be “on” or “above” the reference component toward an opposite direction of gravity.

In addition, unless explicitly described to the contrary, the word “comprise”, “include”, or “contain”, and variations such as “comprises”, “comprising”, “includes”, “including”, “contains” or “containing” will be understood to imply the inclusion of other component rather than the exclusion of any other components.

Further, throughout the specification, a phrase “on a plane”, “in a plane”, “on a plan view”, or “in a plan view” may indicate a case where a portion is viewed from above or a top portion, and a phrase “on a cross-section” or “in a cross-section” may indicate when a cross-section taken along a vertical direction is viewed from a side.

Throughout the specification, when a part is “connected” to another part, it includes not only a case where the part is “directly connected” but also a case where the part is “indirectly connected” with another part in between. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

The use of the term “the” and similar demonstratives may correspond to both the singular and the plural. Operations constituting methods may be performed in any suitable order unless otherwise indicated herein or otherwise clearly contradicted by context and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

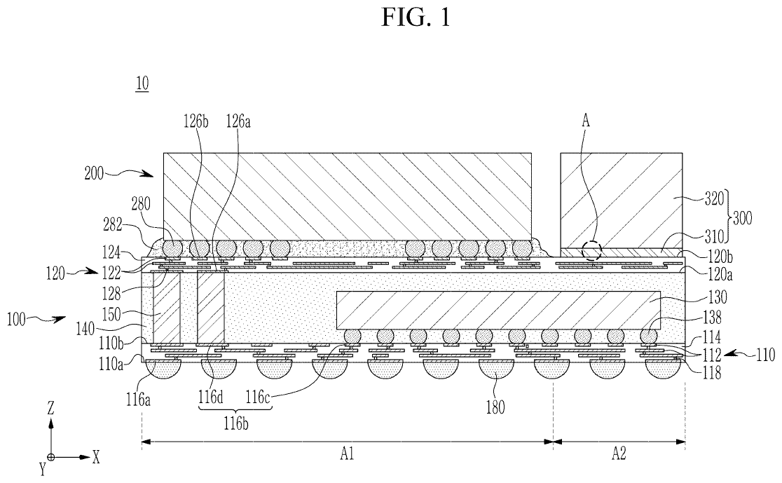

Hereinafter, a stacked semiconductor package according to some example embodiments and one or more modified examples will be described in detail with reference to FIGS. 1 to 5.

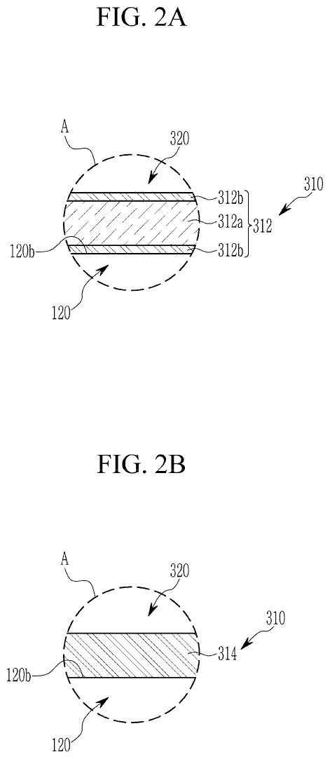

FIG. 1 is a cross-sectional view showing the stacked semiconductor package according to some example embodiments, and FIGS. 2A and 2B are partially enlarged cross-sectional views of region A of FIG. 1, showing various examples of a heat source mark included in the stacked semiconductor package shown in FIG. 1 according to some example embodiments.

Referring to FIG. 1 and FIGS. 2A and 2B, the stacked semiconductor package 10 according to some example embodiments may include a first semiconductor package 100 including a first region A1, a second region A2, and a semiconductor chip 130, a second semiconductor package 200 disposed above or on the first region A1 of the first semiconductor package 100, and a member for heat dissipation 300 (also referred to herein interchangeably as a heat dissipation member) provided in the second region A2 of the first semiconductor package 100 (also referred to interchangeably as the member for heat dissipation 300 being at the second region A2 of the first semiconductor package 100, on the second region A2 of the first semiconductor package 100, or the like). This will be explained in more detail.

In some example embodiments, the stacked semiconductor package 10 may be configured as a package on package (POP). The first semiconductor package 100 may be a lower semiconductor package disposed at a lower portion of the stacked semiconductor package 10, and the second semiconductor package 200 may be an upper semiconductor package disposed at an upper portion of the stacked semiconductor package 10 (e.g., at an upper portion of the first semiconductor package 100).

In some example embodiments, the first semiconductor package 100 may include the semiconductor chip 130. In addition, the first semiconductor package 100 may further include a first redistribution portion 110 (or a first rewiring portion) and a second redistribution portion 120 (or a second rewiring portion) respectively disposed above or on one surface and the other surface of the semiconductor chip 130 (e.g., the first redistribution portion 110 and the second redistribution portion 120 may be at opposite surfaces of the semiconductor chip 130), a mold layer 140 surrounding the semiconductor chip 130 between the first redistribution portion 110 and the second redistribution portion 120, and a through connecting portion 150 (or a penetrating connecting portion) penetrating the mold layer 140 to connect the first redistribution portion 110 and the second redistribution portion 120.

In some example embodiments, the first redistribution portion 110 disposed at the one surface (a lower portion surface of FIG. 1) of the semiconductor chip 130 may be a redistribution portion on which the semiconductor chip 130 is mounted. The first redistribution portion 110 may include a plurality of first redistribution layers 112 with a first insulating layer 114 interposed between the plurality of first redistribution layers 112. The plurality of first redistribution layers 112 may include a first connecting pad 116a or 116b connected to the semiconductor chip 130 and/or the through connecting portion 150.

The plurality of first redistribution layers 112 may be connected to form a desired circuit through a first contact via 118 penetrating the first insulating layer 114 to connect the plurality of first redistribution layers 112 and the first connecting pad 116a or 116b. The plurality of first redistribution layers 112 may perform various functions according to a design. For example, the plurality of first redistribution layers 112 may include a ground pattern, a power pattern, and a signal pattern. The signal pattern may be a pattern for transferring various signals (for example, a data signal and the like) excluding signals applied to the ground pattern and the power pattern. The first contact via 118 may penetrate at least one first insulating layer 114 to connect the plurality of first redistribution layers 112. The first contact via 118 may include a contact via for ground, a contact via for power, a contact via for signal, or the like.

Here, a lowermost redistribution layer among the plurality of first redistribution layers 112 may include the first lower pad 116a disposed at one surface (a lower portion surface of FIG. 1) 110a of the first redistribution portion 110. An uppermost redistribution layer among the plurality of first redistribution layers 112 may include the first upper pad 116b disposed at the other surface 110b (an upper portion surface of FIG. 1) of the first redistribution portion 110.

That is, the one surface 110a of the first redistribution portion 110 may form an outer surface connected to a connecting bump 180, an external circuit, or the like, and the other surface 110b of the first redistribution portion 110 may form a connecting surface on which the semiconductor chip 130 and/or the through connecting portion 150 are disposed. For example, the first lower pad 116a disposed on the one surface 110a of the first redistribution portion 110 may be a pad where the connecting bump 180 connected to a package substrate (not shown) or a mother substrate (not shown) is disposed. The first upper pad 116b disposed on the other surface 110b of the first redistribution portion 110 may be a pad connected to the plurality of first redistribution layers 112 to the semiconductor chip 130 and/or the through connecting portion 150. For example, the first upper pad 116b may include a pad 116c where a connecting member 138 connected to the semiconductor chip 130 is disposed, and a pad 116d connected to the through connecting portion 150.

A portion that functions as a wire in the first redistribution portion 110, the first redistribution layer 112, the first contact via 118, the first lower pad 116a, or the first upper pad 116b may include any of various conductive materials. At least two of the first redistribution layer 112, the first contact via 118, the first lower pad 116a, or the first upper pad 116b may include the same material, or may include different materials. In addition, the first redistribution layer 112, the first contact via 118, the first lower pad 116a, and/or the first upper pad 116b may include a single layer or a plurality of layers. For example, the first redistribution layer 112, the first contact via 118, the first lower pad 116a, and/or the first upper pad 116b may include at least one of copper, aluminum, tungsten, nickel, gold, tin, or titanium or any alloy including the same. The first insulating layer 114 may include any of various insulating materials insulating between the first redistribution layer 112, the first lower pad 116a, and/or the first upper pad 116b that do not have to be connected.

The connecting bump 180 or the connecting member 138 may have a land, ball, or pin shape. The connecting bump 180 or the connecting member 138 may include at least one of copper, aluminum, tungsten, nickel, tin, titanium, tantalum, indium, molybdenum, manganese, cobalt, magnesium, rhenium, beryllium, gallium, or ruthenium or any alloy including the same. For example, the connecting bump 180 or the connecting member 138 may include tin (Sn) or an alloy (for example, a Sn—Ag—Cu alloy) including tin (Sn). However, the example embodiments are not limited thereto, and a shape, a material, or the like of the connecting bump 180 or the connecting member 138 may be modified in various ways. For example, the semiconductor chip 130 may be mounted on the first redistribution portion 110 using a wire bonding method without the connecting member 138.

In some example embodiments, the second redistribution portion 120 disposed on the other surface (an upper portion surface of FIG. 1) of the semiconductor chip 130 may be a redistribution portion or an interposer substrate on which the second semiconductor package 200 is mounted. The second redistribution portion 120 may include a plurality of second redistribution layers 122 with a second insulating layer 124 interposed between the plurality of second redistribution layers 122. The plurality of second redistribution layers 122 may include a second connecting pad 126a or 126b connected to the through connecting portion 150 and/or the second semiconductor package 200.

The plurality of second redistribution layers 122 may be connected to form a desired circuit through a second contact via 128 penetrating the second insulating layer 124 to connect the plurality of second redistribution layers 122 and the second connecting pad 126a or 126b. The plurality of second redistribution layers 122 may perform various functions according to a design. For example, the plurality of second redistribution layers 122 may include a ground pattern, a power pattern, and a signal pattern. The signal pattern may be a pattern for transferring various signals (for example, a data signal and the like) excluding signals applied to the ground pattern and the power pattern. The second contact via 128 may penetrate at least one second insulating layer 124 to electrically connect the plurality of second redistribution layers 122. The second contact via 128 may include a contact via for ground, a contact via for power, a contact via for signal, or the like.

Here, a lowermost redistribution layer among the plurality of second redistribution layers 122 may include a second lower pad 126a connected to the through connecting portion 150. In addition, an uppermost redistribution layer among the plurality of second redistribution layers 122 may include a second upper pad 126b connected to the second semiconductor package 200.

That is, one surface 120a of the second redistribution portion 120 may form a connecting surface on which the through connecting portion 150 is disposed, and the other surface 120b of the second redistribution portion 120 may form a connecting surface on which the second semiconductor package 200 or the like is disposed. For example, the second lower pad 126a disposed on the one surface 120a of the second redistribution portion 120 may be a pad connected to the through connecting portion 150. The second upper pad 126b disposed on the other surface 120b of the second redistribution portion 120 may be a pad where a connecting member 280 connected to the second semiconductor package 200 is disposed.

A portion that functions as a wire in the second redistribution portion 120, the second redistribution layer 122, the second contact via 128, the second lower pad 126a, or the second upper pad 126b may include any of various conductive materials. At least two of the second redistribution layer 122, the second contact via 128, the second lower pad 126a, and the second upper pad 126b may include the same material, or may include different materials. In addition, the second redistribution layer 122, the second contact via 128, the second lower pad 126a, and/or the second upper pad 126b may include a single layer or a plurality of layers. For example, the second redistribution layer 122, the second contact via 128, the second lower pad 126a, and/or the second upper pad 126b may include at least one of copper, aluminum, tungsten, nickel, gold, tin, or titanium or any alloy including the same. The second insulating layer 124 may include any of various insulating materials insulating between the second redistribution layer 122, the second lower pad 126a, and/or the second upper pad 126b that do not have to be connected.

The semiconductor chip 130 may be disposed between the first redistribution portion 110 and the second redistribution portion 120. In further detail, the semiconductor chip 130 may be disposed above or on the other surface 110b of the first redistribution portion 110, may be electrically and physically connected to the first upper pad 116b, and may be spaced apart from the second redistribution portion 120 at a certain distance.

The mold layer 140 surrounding the semiconductor chip 130 may be provided between the first redistribution portion 110 and the second redistribution portion 120. As an example, the mold layer 140 may be disposed between an upper portion surface of the semiconductor chip 130 and the one surface 120a of the second redistribution portion 120, and may be disposed on a side surface of the semiconductor chip 130. In FIG. 1, the mold layer 140 entirely covers the semiconductor chip 130, and entirely fills a space between the first redistribution portion 110 and the second redistribution portion 120 at a portion except for the through connecting portion 150. However, the example embodiments are not limited thereto. The mold layer 140 may include a thermosetting resin such as an epoxy resin, a thermoplastic resin such as polyimide, a resin including an inorganic filler or/and a glass fiber, an epoxy molding compound (EMC), or the like. However, the example embodiments are not limited to a material of the mold layer 140.

The through connecting portion 150 may be formed in the mold layer 140. The through connecting portion 150 may connect the first redistribution portion 110 to the second redistribution portion 120 by penetrating the mold layer 140. For example, the through connecting portion 150 may connect the first upper pad 116b (for example, the pad 116d) of the first redistribution portion 110 and the second lower pad 126a of the second redistribution portion 120. The through connecting portion 150 may include at least one of copper, aluminum, tungsten, nickel, gold, tin, or titanium or any alloy including the same. As an example, the through connecting portion 150 may include copper. However, the example embodiments are not limited thereto, and the through connecting portion 150 may include any of various materials.

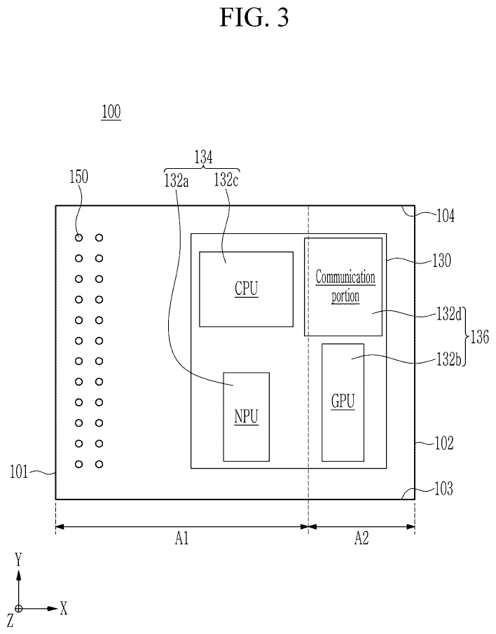

FIG. 3 illustrates that the through connecting portion 150 has a circular shape when viewed in a plan view to have a cylinder shape. However, the example embodiments are not limited thereto. When viewed in a plan view, the through connecting portion 150 may have any of various shapes such as a round shape, an oval shape, a polygon shape, a shape including an angled portion, and the like.

Referring again to FIGS. 1, 2A, and 2B, the second semiconductor package 200 may be mounted on the other surface 120b of the second redistribution portion 120. In some example embodiments, the second semiconductor package 200 may be mounted on the second redistribution portion 120 using a flip-chip bonding method. For example, a connecting pad (not shown) may be disposed on a lower surface of the second semiconductor package 200. The connecting member 280 may be disposed between the second upper pad 126b disposed on the other surface 120b of the second redistribution portion 120 and the connecting pad disposed on the lower surface of the second semiconductor package 200 to electrically connect the second redistribution portion 120 and the second semiconductor package 200.

The connecting member 280 may have a land, ball, or pin shape. The connecting member 280 may include at least one of copper, aluminum, tungsten, nickel, tin, titanium, tantalum, indium, molybdenum, manganese, cobalt, magnesium, rhenium, beryllium, gallium, or ruthenium or any alloy including the same. For example, the connecting member 280 may include tin or an alloy (for example, a Sn—Ag—Cu alloy) including tin. The example embodiments are not limited thereto, and a shape, a material, or the like of the connecting member 280 may be modified in various ways.

An underfill layer 282 surrounding the connecting member 280 may be provided between the other surface (an upper portion surface of FIG. 1) of the first semiconductor package 100 and one surface (a lower portion surface of FIG. 1) of the second semiconductor package 200. The underfill layer 282 may include a thermosetting resin such as an epoxy resin, a thermoplastic resin such as polyimide, a resin including an inorganic filler or/and a glass fiber, an epoxy molding compound, or the like. However, the example embodiments are not limited to a material of the underfill layer 282.

In some example embodiments, the member for heat dissipation 300 may be disposed at the other surface (e.g., the other surface 120b of the second redistribution portion 120) of the first semiconductor package 100. Here, being disposed at the other surface may include both being disposed on (for example, contacting) the other surface and constituting at least a portion of the other surface. For example, at least a portion of the member for heat dissipation 300 may be disposed on (for example, in contact with) the other surface 120b of the second redistribution portion 120, and thus may be disposed on the first semiconductor package 100, or may be configured as a portion of an uppermost redistribution layer disposed at the other surface 120b of the second redistribution portion 120 and thus may constitute at least a portion of the first semiconductor package 100.

The member for heat dissipation 300 may include all members provided for heat dissipation of the stacked semiconductor package 10 or the first semiconductor package 100. For example, the member for heat dissipation 300 may include the heat source mark 310 (e.g., heat source marking) indicating a position where a relatively large amount of heat is emitted or a position requiring heat dissipation, a heat dissipation member 320 (also referred to herein interchangeably as a heat dissipation structure, a heat dissipation device, a heat dissipation block, or the like) that performs heat dissipation through diffusion and/or conduction of heat, a bonding member for bonding the heat dissipation member 320, and the like.

In some example embodiments, the heat source mark 310 may be disposed at the other surface 120b of the second redistribution portion 120, and the heat dissipation member 320 may be disposed on the heat source mark 310.

In some example embodiments, the heat source mark 310 may be disposed at a region where an element (e.g., a second element 132b) that emits a relatively large amount of heat is disposed. The heat source mark 310 may form an uppermost surface or an outer surface of the first semiconductor package 100, or may be disposed above or on an uppermost surface or an outer surface of the first semiconductor package 100. In the present specification, the element (e.g., the second element 132b) that emits the relatively large amount of heat may be referred to as a heating element (or a heat-generating element). This is used for simple explanation and a clear understanding, and the example embodiments are not limited thereto.

For example, the heat source mark 310 may be recognized by the naked eye of a user or a recognition device. As a result, a position of the heating element may be effectively recognized. For example, the position of the heating element may be easily recognized using the heat source mark 310 during an assembly process of the stacked semiconductor package 10, during an attachment process of the heat dissipation member 320, and after the assembly process of the stacked semiconductor package 10. In other words, the heat source mark 310 may be used as a kind of align mark confirming the position of the heating element. As a result, misassembly of the stacked semiconductor package 10, misplacement of the heat dissipation member 320, or the like may be effectively prevented, or the likelihood of such misplacement or misalignment of the heat dissipation member 320 in relation to the stacked semiconductor package 10 may be reduced or minimized, thereby reducing the likelihood of assembly process (e.g., manufacturing process) defects due to such misplacement or misalignment and furthermore improving the reliability of the stacked semiconductor package 10 to provide effective heat dissipation from the first semiconductor package 100 and/or the stacked semiconductor package 10 due to a properly aligned heat dissipation member 320 on the first semiconductor package 100 due to the heat dissipation member 320 being properly aligned and positioned in relation to a heat generating element of the first semiconductor package 100 (e.g., a heat generating element of the semiconductor chip 130) based on the heat dissipation member 320 being aligned and positioned on the heat source mark 310. An image sensor that performs image capturing or the like may be used as the recognition device for the heat source mark 310, but the example embodiments are not limited thereto.

The heat source mark 310 may be used as a bonding member bonding the heat dissipation member 320. Accordingly, the heat dissipation member 320 may be easily bonded to a desired position by disposing the heat dissipation member 320 at a portion where the heat source mark 310 is disposed. That is, the heat dissipation member 320 may be bonded to the first semiconductor package 100 (e.g., the second redistribution portion 120) by the heat source mark 310.

In some example embodiments, the heat source mark 310 may be disposed between the first semiconductor package 100 and the heat dissipation member 320 to include an adhesive layer that bonds the first semiconductor package 100 and the heat dissipation member 320. For example, as shown in FIGS. 2A and 2B, the heat source mark 310 may include an adhesive member 312 (FIG. 2A) or the adhesive layer 314 (FIG. 2B). For example, a thickness of the adhesive member 312 or the adhesive layer 314 may be 10 μm to 100 μm, but the example embodiments are not limited thereto.

In some example embodiments, as shown in FIG. 2A, the adhesive member 312 may include an adhesive film in the form of a film including an adhesive layer 312b.

For example, the adhesive member 312 may include a base member 312a including an insulating material and the adhesive layer 312b disposed on both surfaces of the base member 312a. A thermal conductivity of the base member 312a may be greater than that of the adhesive layer 312b. Accordingly, an effect of dissipating heat by the heat source mark 310 may be increased by the base member 312a. For example, if the base member 312a includes graphite, hexagonal boron nitride (hBN), or the like, the base member 312a may have an excellent thermal conductivity. As another example, the base member 312a may include an organic material, a resin, or the like. The adhesive layer 312b may include any of various insulating materials, any of various organic materials, any of various resins, or the like with an adhesive property.

However, the example embodiments are not limited thereto, and any of various materials may be used as the base member 312a. For example, the thermal conductivity of the base member 312a may be equal to or less than the thermal conductivity of the adhesive layer 312b. In some example embodiments, the adhesive member 312 in the form of the adhesive film may include the adhesive layer 312b without the base member 312a. Numerous other variations are possible.

For example, a die attach film (DAF) or the like may be used as the adhesive film. However, the example embodiments are not limited thereto, and any of various materials, any of various shapes, or the like may be used as the adhesive film included in the adhesive member 312.

In some example embodiments, as shown in FIG. 2B, the adhesive layer 314 may include a single layer of an adhesive material formed by curing (or hardening) an adhesive material in a paste state. The adhesive material in the paste state may include a solid-state filler, and a heat property of the adhesive layer 314 may be changed by the filler. Various materials may be used as the adhesive material in the paste state. In some example embodiments, besides the adhesive material in the paste state, a liquid-state adhesive material may also be used.

For example, the adhesive material in the paste state or a liquid state may be disposed at an upper portion of the first semiconductor package 100, and an annealing process may be performed in a state in which the heat dissipation member 320 is disposed on the adhesive material in the paste state or the liquid state. Then, the adhesive material in the paste state or the liquid state may be cured to form the adhesive layer 314, and the heat dissipation member 320 may be maintained in a state in which the heat dissipation member 320 is adhered to an upper portion of the first semiconductor package 100 by the adhesive layer 314. Accordingly, the heat dissipation member 320 may be stably bonded through an easy process using the adhesive material in the paste state or the liquid state.

The adhesive layer 314 may include any of various insulating materials, any of various organic materials, any of various resins, any of various heat dissipation materials, any of various fillers, or the like with an adhesive property. For example, a thermal interface material (TIM) or the like may be used as the adhesive layer 314. However, the example embodiments are not limited thereto.

The adhesive layer 312b of the adhesive member 312 included in the heat source mark 310, or the adhesive layer 314 included in the heat source mark 310, is disposed between the first semiconductor package 100 and the heat dissipation member 320 to include an adhesive layer that bonds the first semiconductor package 100 and the heat dissipation member 320.

The heat dissipation member 320 may be a member that radiates, diffuses, or conducts heat from the semiconductor chip 130 provided in the first semiconductor package 100 to the outside of the semiconductor chip 130. For example, the heat dissipation member 320 may include a metal lump including a metal (e.g., copper) having an excellent thermal conductivity. As an example, the heat dissipation member 320 may be a heat path block (HPB) having a rectangular parallelepiped shape. Accordingly, the heat dissipation member 320 may have a simple structure so that manufacturing cost (e.g., manufacturing cost to manufacture the stacked semiconductor package 10) is reduced. In some example embodiments, an upper portion surface of the heat dissipation member 320 disposed at an opposite side of the first semiconductor package 100 and an upper portion surface of the second semiconductor package 200 may be disposed on the same plane. In some example embodiments, when the stacked semiconductor package 10 is used, the heat dissipation member 320 may contact another member (e.g., a frame or the like) disposed on the stacked semiconductor package 10. Then, the heat dissipation member 320 may effectively transfer heat of the semiconductor chip 130 to the outside through heat conduction. However, the example embodiments are not limited thereto, and the heat dissipation member 320 may have any of various materials, any of various structures, any of various shapes, or the like.

The stacked semiconductor package 10 according to some example embodiments may include a memory system that stores data, a non-memory system that computes, processes, or controls information, a complex system that combines the memory system and the non-memory system, and the like. The stacked semiconductor package 10 is formed by stacking the second semiconductor package 200 above or on the first semiconductor package 100. As a result, a desired system may be easily implemented by combining the first semiconductor package 100 and the second semiconductor package 200 while reducing an area of the stacked semiconductor package 10.

The drawings and description illustrate that the stacked semiconductor package 10 includes an application processor (AP). However, this is presented as a simple example, and the example embodiments are not limited thereto. The first semiconductor package 100 and/or the second semiconductor package 200 include any of various chips or any of various chiplets performing various roles so that any of various stacked semiconductor packages 10 are formed.

The semiconductor chip 130 included in the first semiconductor package 100 may include a logic chip or a non-memory chip including a central processing unit (CPU), a graphics processing unit (GPU), or the like. For example, the semiconductor chip 130 may include a central processing unit, a graphics processing unit, a neural network processing unit (NPU), a micro controller unit (MCU), a communication portion (or a communication unit), or the like.

The second semiconductor package 200 may include a memory chip that stores data. For example, the second semiconductor package 200 may include a volatile memory chip. As an example, the second semiconductor package 200 may include a dynamic random access memory (DRAM), a static random access memory (SRAM), or the like. However, the example embodiments are not limited thereto, and the second semiconductor package 200 may include a non-volatile memory chip.

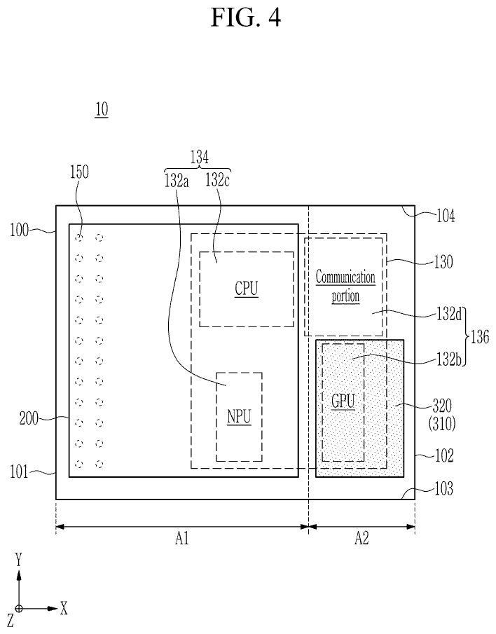

In some example embodiments, the first semiconductor package 100, the second semiconductor package 200, and the member for heat dissipation 300 may have a structure that effectively dissipates heat of the stacked semiconductor package 10. This will be described in more detail with reference to FIGS. 3 and 4.

FIG. 3 is a plan view showing the first semiconductor package included in the stacked semiconductor package shown in FIG. 1. FIG. 4 is a plan view showing the stacked semiconductor package shown in FIG. 1. For a clear understanding, in FIG. 3, the semiconductor chip 130 of the first semiconductor package 100 and a plurality of elements 132a, 132b, 132c, and 132d included in the semiconductor chip 130 are shown as solid lines, and in FIG. 4, the semiconductor chip 130 and the through connecting portion 150 of the first semiconductor package 100 are shown as dotted lines.

Referring to FIG. 3 and FIG. 4, in some example embodiments, the first semiconductor package 100 may have a larger area (e.g., in the XY plane) than each of the second semiconductor package 200 and the heat dissipation member 320. For example, the area of the first semiconductor package 100 (e.g., in the XY plane) may be larger than a sum of an area (e.g., in the XY plane) of the second semiconductor package 200 and an area (e.g., in the XY plane) of the heat dissipation member 320. Accordingly, the second semiconductor package 200 and the heat dissipation member 320 may be stably disposed above or on the first semiconductor package 100.

In some example embodiments, when viewed in a plan view, the first semiconductor package 100 may include the first region A1 and the second region A2 respectively disposed at one side and the other side of a first direction (an X-axis direction of the drawings). The first region A1 may be a portion where the second semiconductor package 200 is disposed, and may include a structure connected to the second semiconductor package 200. The second region A2 may be a portion where the member for heat dissipation 300 is disposed.

As an example, the first region A1 may have a shape extending from one side of the first direction (a left side of the drawings) to a second direction (a Y-axis direction of the drawings). The second region A2 may have a shape extending from the other side of the first direction (a right side of the drawings) to the second direction. In this case, the first region A1 may have a larger size than the second region A2 so that the second semiconductor package 200 is stably disposed at the first region A1. However, the example embodiments are not limited thereto.

When edges disposed on both sides (e.g., opposite sides) of the first direction are referred to as a first edge 101 and a second edge 102, and edges disposed on both sides (e.g., opposite sides) of the second direction are referred to as a third edge 103 and a fourth edge 104, the first region A1 may be a region defined by the first edge 101 and a portion of the third edge 103 and a portion of the fourth edge 104 adjacent to the first edge 101, and the second region A2 may be a region defined by the second edge 102 and another portion of the third edge 103 and another portion of the fourth edge 104 adjacent to the second edge 102.

In some example embodiments, the first region A1 may be disposed at the one side of the first direction, the second region A2 may be disposed at the other side of the first direction, and the second semiconductor package 200 may be disposed at a central region of the first region A1. Accordingly, when viewed in a plan view, the second semiconductor package 200 may not be disposed at a central region of the first semiconductor package 100, but may be shifted toward one side of the first semiconductor package 100. That is, in the first direction (the X-axis direction of the drawings), a distance between one side of the second semiconductor package 200 and one side (the first edge 101) of the first semiconductor package 100 may be less than a distance between the other side of the second semiconductor package 200 and the other side (the second edge 102) of the first semiconductor package 100. As described above, in the stacked semiconductor package 10, the second semiconductor package 200 may have an asymmetric structure.

The semiconductor chip 130 included in the first semiconductor package 100 may be disposed across the first region A1 and the second region A2. In some example embodiments, the semiconductor chip 130 may include at least a portion of the first element 132a disposed in the first region A1 and at least a portion of the second element 132b disposed in the second region A2. An element described to be in the first region A1 may be interchangeably referred to as being on and/or at the first region A1. An element described to be in the second region A2 may be interchangeably referred to as being on and/or at the second region A2. One or a plurality of elements disposed in the first region A1 may be referred to as a first element portion 134, and one or a plurality of elements disposed in the second region A2 may be referred to as a second element portion 136.

In further detail, the semiconductor chip 130 may include the plurality of elements 132a, 132b, 132c, and 132d. Each of the plurality of elements 132a, 132b, 132c, and 132d may include a semiconductor element, a chip, a chiplet, a die, a unit, or the like including at least one of an active element such as a transistor or the like or a passive element such as a capacitor, a resistor, an inductor, or the like.

In FIG. 3, as an example, the plurality of elements 132a, 132b, 132c, and 132d include the first element 132a and the third element 132c disposed at the first region A1, the second element 132b disposed at the second region A2, and the fourth element 132d disposed across the first region A1 and the second region A2. In this case, it may be said that the first element portion 134 basically includes the first element 132a and the third element 132c and the second element portion 136 includes the second element 132b. In FIG. 3, the fourth element 132d is shown as being included in the second element portion 136 where the fourth element 132d has a relatively large area, but the example embodiments are not limited thereto. For example, it may be said that the fourth element 132d is included in each of the first element portion 134 and the second element portion 136.

In the present specification, expressions such as the first element, the second element, the third element, and the fourth element are terms used to distinguish between embodiments or modified examples. Therefore, in some example embodiments, including for example the modified examples, elements included in the first element, the second element, the third element, and the fourth element may all be different.

In some example embodiments, a heating element capable of dissipating a relatively large amount of heat may be disposed at (e.g., disposed in) the second region A2 and the member for heat dissipation 300 may be disposed at the second region A2 so that heat produced by the heating element is effectively dissipated. The member for heat dissipation 300 may be disposed at the second region A2 to at least partially overlap the heating element in the second region A2, for example in the Z-axis direction which may be referred to as a vertical direction extending perpendicular to an in-plane direction of the first semiconductor package 100 (e.g., perpendicular to the X-axis direction and/or Y-axis direction and thus perpendicular to the XY plane) so that heat produced by the heating element is effectively dissipated (e.g., effective dissipated in the +Z-axis direction) by the vertically-overlapped member for heat dissipation 300, thereby improving heat dissipation efficiency and/or performance of at least the first semiconductor package 100 and thus improving performance of the first semiconductor package 100 and any stacked semiconductor package 10 including same. The Z-axis direction, being perpendicular to an in-plane direction of the first semiconductor package 100, may be perpendicular to one or more surfaces of the first semiconductor package 100, where such one or more surfaces may include the surface 120b, the surface 120a, the surface 110a, the surface 110b, any combination thereof, or the like.

In some example embodiments, the first element 132a of the first element portion 134 disposed at the first region A1 may be a low-power element driven by relatively low electric power. For example, the first element 132a may consume a relatively small amount of electric power during operation and/or may have a relatively low rate of electric power consumption during operation. The second element 132b of the second element portion 136 disposed at the second region A2 may be a high-power element driven by relatively high electric power. For example, the second element 132b may consume a relatively large amount of electric power during operation and/or may have a relatively high rate of electric power consumption during operation. That is, the second element 132b may be a higher power element than the first element 132a. For example, the second element 132b may consume a larger amount of electric power than the first element 132a during operation and/or may have a higher rate of electric power consumption than the first element 132a during operation.

In this case, the second element 132b may be an element driven by the highest power (e.g., an element having a highest amount and/or rate of electric power consumption during operation) among the plurality of elements 132a, 132b, 132c, and 132d, but an element driven by higher power than the second element 132b may be provided among the plurality of elements 132a, 132b, 132c, and 132d. In other words, the second element 132b may be driven by higher power than the first element 132a of the first element portion 134 disposed at the first region A1, and does not have to be an element driven by the highest power. The higher the power (e.g., the higher the amount of power consumption by an element and/or the higher the rate of power consumption by an element), the more likely it (e.g., the element) is to emit heat, but even if an element is not driven by the highest power, the element may emit more heat than an element driven by the highest power depending on usage environment. For example, even if the element is not driven by the highest power, the element may emit more heat than the element driven by the highest power if it is used for a long time.

For example, the first element 132a may be driven by the lowest power among the elements provided in the first element portion 134 disposed at the first region A1. However, the example embodiments are not limited thereto. Considering a design, usage environment, or the like of the plurality of elements 132a, 132b, 132c, and 132d, an element driven by lower power than the first element 132a may be disposed at (e.g., in) the first region A1 and/or the second region A2.

That is, in some example embodiments, the first element 132a included in the first element portion 134 and the second element 132b included in the second element portion 136 are compared, and all elements included in the first element portion 134 and all elements included in the second element portion 136 are not compared. It may be necessary to adjust positions of the plurality of elements 132a, 132b, 132c, and 132d disposed at the first region A1 and the second region A2 depending on areas thereof, there may be elements that need to be adjacent to or spaced apart from each other depending on the design, and the heating element may be changed depending on the usage environment.

In some example embodiments, the second element 132b may have a finer wiring structure or a finer pattern than the first element 132a. Accordingly, wiring density, pattern density, or element density of the second element 132b may be greater than wiring density, pattern density, or element density of the first element 132a. For example, a node of the second element 132b may be less than a node of the first element 132a. Here, having the fine wiring structure or the fine pattern may mean that a length of a contact gate or a wire such as a contact gate pitch or a wiring pitch is smaller. In some example embodiments, the having the fine wiring structure or the fine pattern may mean that a node of a manufacturing process has a smaller value. For example, the second element 132b may be formed by a leading node, and the first element 132a may be formed by a legacy node. In some example embodiments, the having the fine wiring structure or the fine pattern may mean that density or the number (e.g., quantity) of transistors is greater. For example, the second element 132b may have a greater density or quantity of transistors than the first element 132a.

In some example embodiments, the second element 132b may include at least one of a central processing unit (CPU) or a graphics processing unit (GPU), and the first element 132a may include a neural network processing unit, a micro controller unit, a communication portion (or a communication unit), or the like.

The second element 132b that is driven by the high power, has the fine wiring structure or the fine pattern, or includes the central processing unit and/or the graphics processing unit, may generate relatively more heat than the first element 132a when the stacked semiconductor package 10 is driven.

FIG. 3 illustrates that the first element 132a includes the neural network processing unit and the second element 132b includes the graphics processing unit. In addition, FIG. 3 illustrates that the third element 132c disposed at the first region A1 includes the central processing unit and the fourth element 132d provided at the first region A1 and the second region A2 includes the communication portion. According to the design, the third element 132c driven by relatively large power such as the central processing unit, may be disposed at the first region A1, and the fourth element 132d driven by relatively small power such as the communication portion, may be disposed at the second region A2. However, the example embodiments are not limited thereto. The first element portion 134 may include one or a plurality of elements, and the second element portion 136 may include one or a plurality of elements. Additionally, elements included in the first element portion 134 and the second element portion 136 may be modified in various ways.

In other words, dispositions, types, or the like of the plurality of elements 132a, 132b, 132c, and 132d may be modified in various ways.

In some example embodiments, the semiconductor chip 130 may be disposed at the first region A1 and the second region A2, so that the semiconductor chip 130 is shifted toward from the first direction (the X-axis direction of the drawings) to the other side (the right side of the drawings). When viewed in a plan view, the semiconductor chip 130 may not be disposed at the central region of the first semiconductor package 100, but may be shifted toward the other side of the first semiconductor package 100. That is, in the first direction (the X-axis direction of the drawings), a distance between one side of the semiconductor chip 130 (the left side of the drawings) and the one side (the first edge 101) of the first semiconductor package 100 may be greater than a distance between the other side of the semiconductor chip 130 (the right side of the drawings) and the other side (the second edge 102) of the first semiconductor package 100. As described above, in the first semiconductor package 100, the semiconductor chip 130 may have an asymmetric structure.

As described above, the second semiconductor package 200 may be disposed above or on the first region A1, and the through connecting portion 150 may be provided in the first region A1 to connect the first redistribution portion 110 and the second redistribution portion 120. In addition, the heat source mark 310 that overlaps (e.g., overlaps in the Z-axis direction extending perpendicular to an in-plane direction of the first semiconductor package 100) at least a portion of the second element 132b or the second element portion 136 may be provided in the second region A2, and the heat dissipation member 320 may be bonded on the heat source mark 310. For example, the member for heat dissipation 300 may overlap at least a portion of the second element 132b or the second element portion 136 in the Z-axis direction (also referred to herein as a vertical direction) which may extend perpendicular to an in-plane direction of the first semiconductor package 100. In some example embodiments, the member for heat dissipation 300 may overlap an entire portion (e.g., an entirety) of the second element 132b or the second element portion 136 in the Z-axis direction.

The through connecting portion 150 may be provided at the first region A1, and may not be provided at the second region A2 (e.g., may be absent from the second region A2). In further detail, the through connecting portion 150 may be disposed at one side (the left side of the drawings) adjacent to the first edge 101 in the first semiconductor package 100, and may not be provided at the other side (the right side of the drawings) where the semiconductor chip 130 is disposed. Accordingly, the through connecting portion 150 may be disposed to have an asymmetric structure based on the first semiconductor package 100 or the second semiconductor package 200. Accordingly, a distance between the through connecting portion 150 and the second semiconductor package 200 may be minimized while considering a position of the semiconductor chip 130.

FIG. 3 illustrates that the through connecting portion 150 has a plurality of rows in the second direction (the Y-axis direction of the drawings) and a plurality of columns in the first direction (the X-axis direction of the drawings) along the first edge 101. However, the example embodiments are not limited thereto.

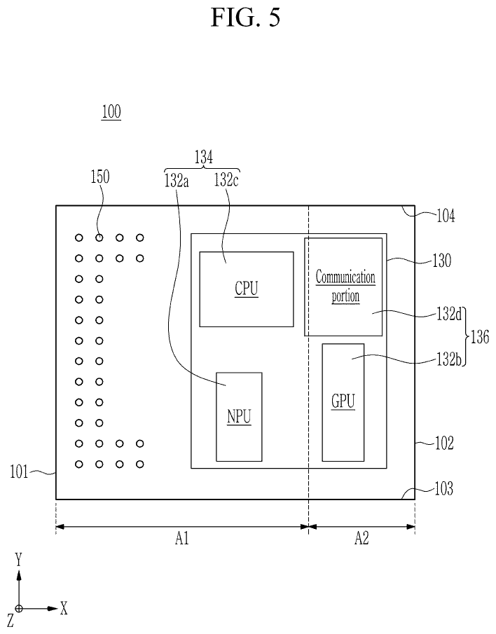

FIG. 5 is a plan view showing a modified example of the first semiconductor package included in the stacked semiconductor package shown in FIG. 1.

As a modified example, as shown in FIG. 5, the through connecting portion 150 may be further provided at a portion adjacent to the third edge 103 and/or the fourth edge 104 along the third edge 103 and/or the fourth edge 104 in the second direction at the first region A1. Accordingly, the number (e.g., quantity), formation areas, or the like of through connecting portions 150 may be sufficiently secured. In some example embodiments, the through connecting portion 150 may have a single column, and may have no regular disposition, and numerous other variations thereof are possible.

Referring again to FIGS. 3 and 4, the heat source mark 310 may be provided to overlap at least a portion of the second element 132b of the semiconductor chip 130 above or on the second region A2. As a result, the heat dissipation member 320 may overlap (e.g., in the Z-axis direction) at least a portion of the second element 132b.

In some example embodiments, the heat source mark 310 may be disposed to overlap (e.g., in the Z-axis direction) an entire portion of the second element 132b. When viewed in a plan view, a size (e.g., area in the XY plane) of the heat source mark 310 may be equal to or greater than a size (e.g., area in the XY plane) of the second element 132b. As a result, the heat dissipation member 320 may be disposed to overlap (e.g., in the Z-axis direction) the entire portion of the second element 132b. In addition, when viewed in a plan view, a size of the heat dissipation member 320 may be equal to or greater than the size of the second element 132b.

Since heat emitted from the semiconductor chip 130 is released in a horizontally diffused form toward an upper portion surface of the first semiconductor package 100 (e.g., surface 120b), heat dissipation at a large area (e.g., a large area in the XY plane) may be needed at the upper portion surface of the first semiconductor package 100 than the second element 132b of the semiconductor chip 130 (e.g., a larger area in the XY plane than an area in the XY plane of the second element 132b). When the heat source mark 310 or the heat dissipation member 320 is formed greater than the second element 132b (e.g., when the heat source mark 310 or the heat dissipation member 320 overlapping at least a portion of the second element 132b in the Z-axis direction has a larger area in the XY plane than the second element 132b), heat emitted from the second element 132b may be effectively dissipated.

However, the example embodiments are not limited thereto. Therefore, the heat source mark 310 or the heat dissipation member 320 may be disposed to overlap (e.g., in the Z-axis direction) a portion of the second element 132b. In some example embodiments, when viewed in a plan view, a size of the heat source mark 310 or the heat dissipation member 320 may be less than the size of the second element 132b.

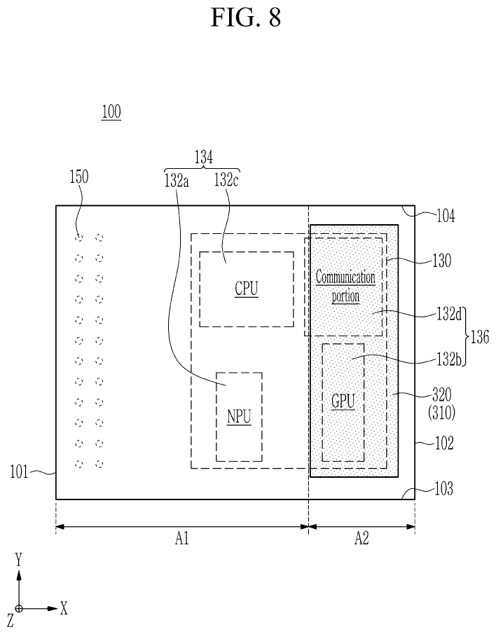

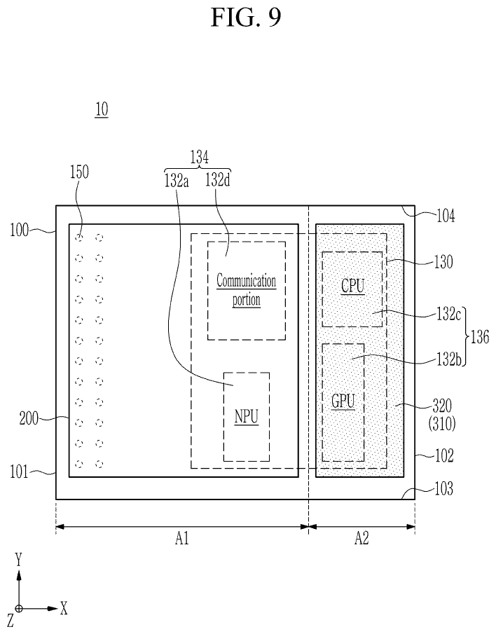

FIG. 3 illustrates that the heat source mark 310 and/or the heat dissipation member 320 are formed at a portion where the second element 132b that is a portion of the second element portion 136 is disposed (e.g., the heat source mark 310 and/or the heat dissipation member 320 overlap the second element 132b in the Z-axis direction), and is not formed at a portion of a portion where the fourth element 132d is disposed (e.g., the heat source mark 310 and/or the heat dissipation member 320 do not overlap the fourth element 132d in the Z-axis direction). Accordingly, the heat source mark 310 and/or the heat dissipation member 320 may be formed at a portion where a lot of heat is emitted to increase heat dissipation efficiency (e.g., heat dissipation performance of the first semiconductor package 100 and/or of the stacked semiconductor package 10), and the heat source mark 310 and/or the heat dissipation member 320 may not be disposed at a portion other than the portion where a lot of heat is emitted so that cost (e.g., manufacturing costs of the first semiconductor package 100 and/or of the stacked semiconductor package 10) is reduced. However, the example embodiments are not limited thereto. A modified example thereof will be described in more detail later with reference to FIGS. 8 and 9.

FIG. 3 illustrates that the heat dissipation member 320 is disposed at the same position or substantially the same position as the heat source mark 310 to have the same area. However, the example embodiments are not limited thereto. For example, an area of the heat dissipation member 320 may be greater than an area of the heat source mark 310. In another example, an area of the heat dissipation member 320 may be less than the area of the heat source mark 310.

In some example embodiments, the heat source mark 310 may be used as a bonding member bonding the heat dissipation member 320, so that the heat dissipation member 320 is effectively disposed in response to a portion of the semiconductor chip 130 where heat is likely to be generated.

According to some example embodiments, heat of the semiconductor chip 130 included in the first semiconductor package 100 disposed at a lower portion of the stacked semiconductor package 10 may be effectively radiated to the outside (e.g., an exterior of the stacked semiconductor package 10). That is, by disposing the second element 132b that may generate a relatively large amount of heat and the member for heat dissipation 300 at the second region A2, heat generated from the semiconductor chip 130 may be effectively discharged to the outside through the member for heat dissipation 300, thereby improving heat dissipation efficiency and/or performance of the stacked semiconductor package 10 and thus improving the performance of the stacked semiconductor package 10. In addition, a space may be efficiently used by disposing the second semiconductor package 200 and/or the through connecting portion 150 at the first region A1.

In some example embodiments, the heat source mark 310 may be used as an align mark (or an alignment mark) for aligning the heat dissipation member 320 and/or as a bonding member for bonding the heat dissipation member 320. Accordingly, the heat dissipation member 320 may be efficiently aligned and bonded using a simple structure, thereby reducing complexity of the stacked semiconductor package 10 and/or the process for manufacturing the stacked semiconductor package 10, thereby reducing the likelihood of manufacturing process defects based on the reduced complexity, thereby improving reliability of the stacked semiconductor package 10 based on such reduced likelihood of process defects.

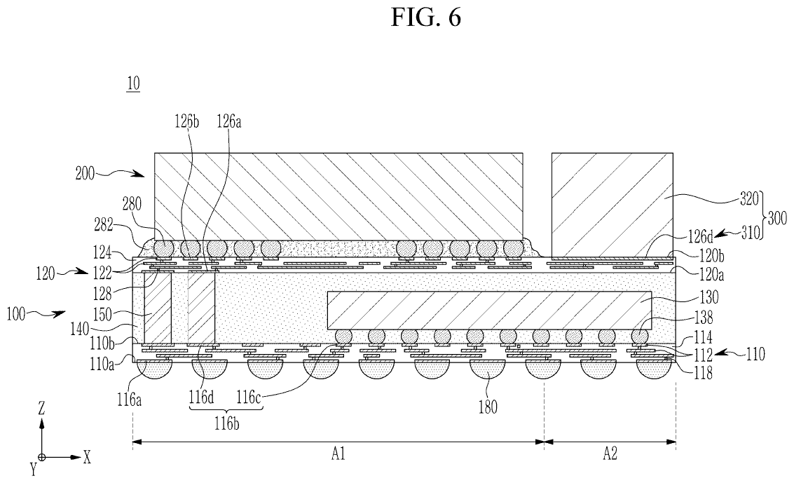

Hereinafter, a stacked semiconductor package according to a modified example and/or some example embodiments different from the above-described example embodiments will be described in more detail with reference to FIGS. 6 to 9. A detailed description of a portion identical to or extremely similar to the portion already described will be omitted, and other portions will be described in detail.

FIG. 6 is a cross-sectional view showing a stacked semiconductor package according to some example embodiments.

Referring to FIG. 6, in some example embodiments, the heat source mark 310 may be formed of a wiring portion 126d that is a portion of an uppermost redistribution layer among the plurality of second redistribution layers 122 included in the second redistribution portion 120 (e.g., a portion of an outermost wiring layer of the second redistribution portion 120) of the first semiconductor package 100. Here, an uppermost redistribution layer in the second redistribution portion 120 may be an outermost redistribution layer in the second redistribution portion 120 or a redistribution layer constituting an outer surface of the second redistribution portion 120.

In further detail, the uppermost redistribution layer among the plurality of second redistribution layers 122 may include the second upper pad 126b disposed at the first region A1 and connected to the second semiconductor package 200, and the wiring portion 126d disposed at the second region A2 and constituting the heat source mark 310. In this case, the wiring portion 126d may have the same thickness as that of the second upper pad 126b.

Accordingly, the heat source mark 310 and/or the wiring portion 126d may form the same layer as the uppermost redistribution layer among the plurality of second redistribution layers 122, may have the same thickness as that of the uppermost redistribution layer among the plurality of second redistribution layers 122 or the second upper pad 126b, and may be made of the same material as the uppermost redistribution layer among the plurality of second redistribution layers 122 or the second upper pad 126b.

For example, a thickness of the uppermost redistribution layer, the second upper pad 126b, or the wiring portion 126d may be 1 nm to 20 nm (for example, 5 nm to 15 nm), but the example embodiments are not limited thereto. In addition, the heat source mark 310 may include a metal. As an example, the heat source mark 310 may include at least one of copper, aluminum, tungsten, nickel, gold, tin, or titanium or any alloy including the same.

However, the example embodiments are not limited thereto, and the wiring portion 126d may be formed separately from the uppermost redistribution layer or the second upper pad 126b, so that a thickness or a material of the wiring portion 126d is different from a thickness or a material of the uppermost redistribution layer or the second upper pad 126b.

In some example embodiments, the second upper pad 126b may be connected to other wires of the plurality of second redistribution layers 122. That is, the second upper pad 126b may be electrically connected to a redistribution layer other than the uppermost redistribution layer among the plurality of second redistribution layers 122. For example, the second upper pad 126b may be electrically connected to the redistribution layer other than the uppermost redistribution layer by the second contact via 128.

In some example embodiments, the heat source mark 310 or the wiring portion 126d may be configured as a floating wiring portion that is not connected to the other wires (e.g., any other wires) of the plurality of second redistribution layers 122. That is, when viewed in a plan view, the heat source mark 310 or the wiring portion 126d may have a shape that is completely spaced apart from (e.g., isolated from direct contact with) the second upper pad 126b. The heat source mark 310 or the wiring portion 126d may not be electrically connected to the redistribution layer other than the uppermost redistribution layer among the plurality of second redistribution layers 122. For example, the heat source mark 310 may be electrically separated from the redistribution layer other than the uppermost redistribution layer by the second insulating layer 124.

The heat source mark 310 may be formed in a process of forming or patterning the uppermost redistribution layer among the plurality of second redistribution layers 122, and may form a portion of the second redistribution portion 120. Then, a manufacturing process may be simplified because a separate process for forming the heat source mark 310 does not need to be performed, thereby reducing the likelihood of manufacturing process defects in the stacked semiconductor package 10 due to reduced complexity of the manufacturing process.

In some example embodiments, an upper portion surface of the heat source mark 310 may be disposed at the same plane as (e.g., coplanar or substantially coplanar with) the other surface 120b of the second redistribution portion 120, and the heat source mark 310 may include a metal layer embedded in the second redistribution portion 120.

In some example embodiments, the heat source mark 310 may be disposed at a region where an element (e.g., the second element 132b) that emits a relatively large amount of heat is disposed. The heat source mark 310 may form a portion of an uppermost surface or an outer surface of the first semiconductor package 100.

For example, the heat source mark 310 may be used as a kind of align mark. The heat source mark 310 may be used as a bonding member bonding the heat dissipation member 320. Accordingly, the heat dissipation member 320 may be easily bonded to a desired position by disposing the heat dissipation member 320 at a portion where the heat source mark 310 is disposed. That is, the heat dissipation member 320 may be bonded to the first semiconductor package 100 (e.g., the second redistribution portion 120) by the heat source mark 310.

For example, the heat source mark 310 and the heat dissipation member 320 may be directly bonded by a hybrid bonding. That is, the other surface of the heat source mark 310 constituting the other surface 120b of the second redistribution portion 120 and one surface of the heat dissipation member 320 facing the other surface of the heat source mark 310 may be bonded by the hybrid bonding including a metal bonding. Therefore, a separate adhesive layer, a separate adhesive material, or the like may not be provided between the heat source mark 310 that is a portion of the second redistribution portion 120 and the heat dissipation member 320.

The heat source mark 310 and the heat dissipation member 320 may have excellent bonding strength due to a bonding (e.g., a metal bonding) by mutual diffusion of metals (e.g., copper) constituting the heat source mark 310 and the heat dissipation member 320 in an annealing process for the hybrid bonding.

For example, the heat source mark 310 and the heat dissipation member 320 may include copper so that the metal bonding of the heat source mark 310 and the heat dissipation member 320 includes a copper-to-copper bonding. In some example embodiments, the heat source mark 310 and/or the heat dissipation member 320 may be made of copper, and a layer including copper may be provided at a bonding surface between the heat source mark 310 and the heat dissipation member 320.

The heat source mark 310 and the heat dissipation member 320 may be bonded by the metal bonding, so that the hybrid bonding has an excellent heat dissipation property compared with a case where the metal bonding is not provided. For example, the hybrid bonding may have heat dissipation efficiency that is about 20% or more excellent compared with a case of bonding using an insulating material.

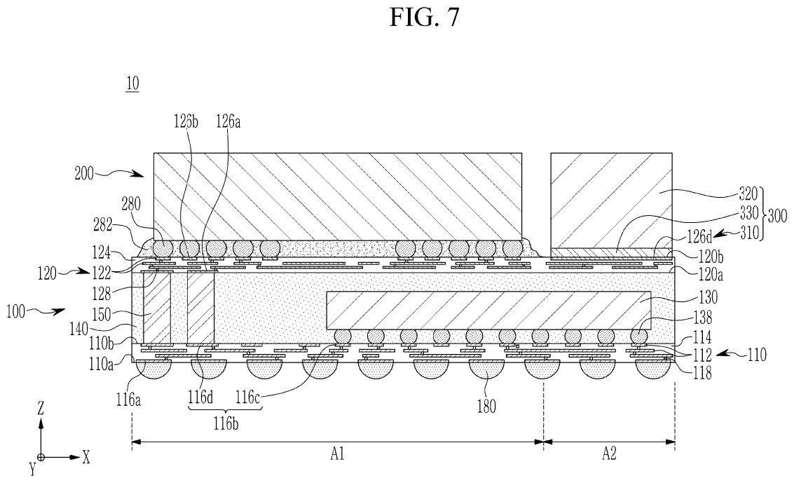

FIG. 7 is a cross-sectional view showing a stacked semiconductor package according to some example embodiments.

Referring to FIG. 7, in some example embodiments, the heat source mark 310 may be configured as the portion of the uppermost redistribution layer among the plurality of second redistribution layers 122 included in the second redistribution portion 120 of the first semiconductor package 100 (e.g., a portion of an outermost wiring layer of the second redistribution portion 120). Description of the heat source mark 310 may be applied to description of the heat source mark 310 of some example embodiments, including example embodiments of FIG. 6.

In some example embodiments, a separate bonding member 330 may be further included between the heat source mark 310 and the heat dissipation member 320 to bond the heat source mark 310 and the heat dissipation member 320. The bonding member 330 may be provided as an adhesive member including an adhesive film in the form of a film including an adhesive material, or may include an adhesive layer formed by curing an adhesive material in a paste state or a liquid state.

Here, description of the adhesive member that may be used as the bonding member 330 may be applied to description of the adhesive member 312 described with reference to FIG. 2A. Description of the adhesive layer that may be used as the bonding member 330 may be applied to description of the adhesive layer 314 described with reference to FIG. 2B.

Even when the heat source mark 310 includes the wiring portion 126d that is the portion of the uppermost redistribution layer among the plurality of second redistribution layers 122, the heat source mark 310 and the heat dissipation member 320 may be bonded by providing the separate bonding member 330. In this case, the heat source mark 310 may be used as a kind of align mark.

FIG. 8 is a plan view showing a stacked semiconductor package according to a modified example according to some example embodiments.

Referring to FIG. 8, in the modified example, the heat source mark 310 and/or the heat dissipation member 320 may be disposed to overlap (e.g., in the Z-axis direction) an entire portion of the second element portion 136. When viewed in a plan view, the heat source mark 310 and/or the heat dissipation member 320 may be disposed to overlap the entire portion of the second element portion 136 (e.g., the second element 132b and/or the fourth element 132d) disposed at the second region A2. Accordingly, a heat dissipation effect by the heat dissipation member 320 may be improved, thereby improving heat dissipation efficiency and/or performance of the first semiconductor package 100 and/or of the stacked semiconductor package 10.

FIG. 8 illustrates that the plurality of elements 132a, 132b, 132c, and 132d include the first element 132a and the third element 132c disposed at the first region A1, the second element 132b disposed at the second region A2, and the fourth element 132d disposed across the first region A1 and the second region A2. In addition, FIG. 8 illustrates that the first element 132a includes the neural network processing unit and the second element 132b includes the graphics processing unit. In addition, FIG. 8 illustrates that the third element 132c disposed at the first region A1 includes the central processing unit and the fourth element 132d disposed at the first region A1 and the second region A2 includes the communication portion.

However, the example embodiments are not limited thereto, and dispositions, types, or the like of the plurality of elements 132a, 132b, 132c, and 132d may be modified in various ways.

FIG. 9 is a plan view showing a stacked semiconductor package according to another modified example according to some example embodiments. Referring to FIG. 9, in some example embodiments, the plurality of elements 132a, 132b, 132c, and 132d may include the first element 132a and the fourth element 132d disposed at the first region A1 and the second element 132b and the third element 132c disposed at the second region A2.

In some example embodiments, the second element 132b disposed at the second region A2 may be a high-power element driven by higher power than each of the first element 132a and the fourth element 132d disposed at the first region A1. The third element 132c disposed at the second region A2 may be a high-power element driven by higher power than each of the first element 132a and the fourth element 132d disposed at the second region A2. The first element 132a and the fourth element 132d disposed at the first region A1 may be a low-power element driven by lower power than the second element 132b and the third element 132c disposed at the second region A2. That is, the first element portion 134 disposed at the first region A1 may include one or a plurality of low-power elements, and the second element portion 136 disposed at the second region A2 may include one or a plurality of high-power elements.

In some example embodiments, the second element 132b disposed at the second region A2 may have a finer wiring structure or a finer pattern than each of the first element 132a and the fourth element 132d disposed at the first region A1. Accordingly, wiring density, pattern density, or element density of the second element 132b may be greater than wiring density, pattern density, or element density of each of the first element 132a and the fourth element 132d. In some example embodiments, a node of the second element 132b may be less than a node of each of the first element 132a and the fourth element 132d. In some example embodiments, a density or the number (e.g., quantity) of transistors of the second element 132b may be greater than a density or the number of transistors of each of the first element 132a and the fourth element 132d.

In addition, the third element 132c disposed at the second region A2 may have a finer wiring structure or a finer pattern than each of the first element 132a and the fourth element 132d disposed at the first region A1. Accordingly, wiring density, pattern density, or element density of the third element 132c may be greater than wiring density, pattern density, or element density of each of the first element 132a and the fourth element 132d. In some example embodiments, a node of the third element 132c may be less than a node of each of the first element 132a and the fourth element 132d. In some example embodiments, a density or the number of transistors of the third element 132c may be greater than a density or the number of transistors of each of the first element 132a and the fourth element 132d.

In some example embodiments, the first element 132a or the fourth element 132d may include the neural network processing unit, the micro controller unit, the communication portion, or the like. In addition, the second element 132b or the third element 132c may include the central processing unit, the graphics processing unit, or the like.

As described above, an element that may generate relatively less heat may be disposed at the first region A1, and a heating element that may generate relatively more heat may be disposed at the second region A2. Then, heat generated by the heating element disposed at the second region A2 may be effectively dissipated by the member for heat dissipation 300 provided at the second region A2.

FIG. 9 illustrates that each of the first element 132a and the fourth element 132d constituting the first element portion 134 includes the neural network processing unit and the communication portion. In addition, FIG. 9 illustrates that each of the second element 132b and the third element 132c constituting the second element portion 136 includes the graphics processing unit and the central processing unit. However, the example embodiments are not limited thereto, and dispositions, types, or the like of the plurality of elements 132a, 132b, 132c, and 132d may be modified in various ways.

In some example embodiments, the heat source mark 310 may overlap (e.g., in the Z-axis direction) at least a portion of a plurality of elements (i.e., the second element 132b and the third element 132c) included in the second element portion 136 above or on the second region A2.

In some example embodiments, the heat source mark 310 may be disposed to overlap an entire portion of the plurality of elements (i.e., the second element 132b and the third element 132c) included in the second element portion 136. When viewed in a plan view, a size of the heat source mark 310 may be equal to or greater than a sum of sizes of the plurality of elements (i.e., the second element 132b and the third element 132c) included in the second element portion 136. As a result, the heat dissipation member 320 may be disposed to overlap the entire portion of the plurality of elements (i.e., the second element 132b and the third element 132c) included in the second element portion 136. When viewed in a plan view, a size of the heat dissipation member 320 may be equal to or greater than the sum of the sizes of the plurality of elements (i.e., the second element 132b and the third element 132c) included in the second element portion 136.

As an example, the heat source mark 310 and/or the heat dissipation member 320 may be disposed to overlap an entire portion of the second element portion 136. When viewed in a plan view, a size of the heat source mark 310 and/or the heat dissipation member 320 may be equal to or greater than the sum of the sizes of the second element portion 136.

As described above, if the heat source mark 310 or the heat dissipation member 320 is formed with a sufficient area, heat emitted from the second element portion 136 may be effectively dissipated.

However, the example embodiments are not limited thereto. Therefore, the heat source mark 310 or the heat dissipation member 320 may be disposed to overlap a portion of the second element portion 136 or a portion of the plurality of elements (i.e., the second element 132b and the third element 132c) included in the second element portion 136. In some example embodiments, when viewed in a plan view, a size of the heat source mark 310 or the heat dissipation member 320 may be less than the sum of the sizes of the second element portion 136 or the sum of the sizes of the plurality of elements (i.e., the second element 132b and the third element 132c) included in the second element portion 136.

According to some example embodiments, a heating element that may emit a relatively large amount of heat may be entirely disposed at the second region A2 so that heat is effectively dissipated through the heat dissipation member 320.

As described herein, any devices, systems, units, blocks, circuits, controllers, processors, and/or portions thereof according to any of the example embodiments (including, for example, the stacked semiconductor package 10, the first semiconductor package 100, the second semiconductor package 200, the semiconductor chip 130, the first element 132a, the second element 132b, the third element 132c, the fourth element 132d, any portion thereof, or the like) may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid-state drive memory device, storing a program of instructions, and a processor (e.g., CPU) configured to execute the program of instructions to implement the functionality and/or methods performed by some or all of any devices, systems, units, blocks, circuits, controllers, processors, and/or portions thereof according to any of the example embodiments.

Although some example embodiments have been described in detail above, the scope of the present inventive concepts is not limited thereto. Various modifications and improvements made by those skilled in the art using basic concepts of the present inventive concepts defined in the following claims also belong to the scope of right of the present inventive concepts.

What is claimed is:

1. A stacked semiconductor package, comprising:
a first semiconductor package that includes a first region and a second region, the first semiconductor package including a semiconductor chip, the semiconductor chip including a first element at the first region and a second element at the second region;
a second semiconductor package on the first region of the first semiconductor package; and
a member for heat dissipation that is disposed at the second region of the first semiconductor package, the member for heat dissipation overlapping at least a portion of the second element in a vertical direction, the vertical direction extending perpendicular to an in-plane direction of the first semiconductor package.

2. The stacked semiconductor package of claim 1, wherein the second element is a higher power element than the first element.

3. The stacked semiconductor package of claim 1, wherein the second element has a finer wiring structure or a finer pattern than the first element.

4. The stacked semiconductor package of claim 1, wherein the second element includes at least one of a central processing unit (CPU) or a graphics processing unit (GPU).

5. The stacked semiconductor package of claim 1, wherein the member for heat dissipation overlaps an entire portion of the second element in the vertical direction.

6. The stacked semiconductor package of claim 1, wherein a size or an area of the member for heat dissipation is equal to or greater than a size or an area of the second element in a plan view.

7. The stacked semiconductor package of claim 1, wherein the member for heat dissipation includes a heat source mark.

8. The stacked semiconductor package of claim 7, wherein the heat source mark includes an adhesive layer between the first semiconductor package and the member for heat dissipation.

9. The stacked semiconductor package of claim 7, wherein the heat source mark is configured as a portion of an outermost wiring layer of a redistribution portion included in the first semiconductor package.

10. The stacked semiconductor package of claim 9, wherein the heat source mark is configured as a floating wiring portion that is not connected to any other wire of the redistribution portion.

11. The stacked semiconductor package of claim 1, wherein the member for heat dissipation includes
a heat source mark configured as a bonding member, and
a heat dissipation member bonded to the heat source mark.

12. The stacked semiconductor package of claim 11, wherein
the heat source mark is configured as a portion of an outermost wiring layer of a redistribution portion included in the first semiconductor package, and
the heat source mark and the heat dissipation member are directly bonded by a hybrid bonding or are bonded using a separate adhesive layer.

13. The stacked semiconductor package of claim 11, wherein
the heat dissipation member includes a metal, and
one surface of the second semiconductor package at an opposite side of the first semiconductor package and one surface of the heat dissipation member are coplanar.

14. The stacked semiconductor package of claim 1, wherein the first semiconductor package further includes
a first redistribution portion and a second redistribution portion respectively on opposite surfaces of the semiconductor chip,
a mold layer surrounding the semiconductor chip between the first redistribution portion and the second redistribution portion, and
a through connecting portion that penetrates the mold layer to connect the first redistribution portion and the second redistribution portion, the through connecting portion at the first region.

15. The stacked semiconductor package of claim 1, wherein
the first region is at one side of one direction of the first semiconductor package and the second region is at another side of the one direction of the first semiconductor package, and
the semiconductor chip is shifted toward the other side of the one direction.

16. A stacked semiconductor package, comprising:
a first semiconductor package that includes a first region and a second region, the first semiconductor package including a semiconductor chip, the semiconductor chip including a first element at the first region and a second element at the second region, the second element being a higher power element than the first element;
a second semiconductor package at the first region of the first semiconductor package; and
a heat source mark at the second region to overlap at least a portion of the second element in a vertical direction, the vertical direction extending perpendicular to an in-plane direction of the first semiconductor package.

17. The stacked semiconductor package of claim 16, wherein
the heat source mark is configured as a bonding member, and
the stacked semiconductor package further comprises a heat dissipation member bonded to the second region of the first semiconductor package by the heat source mark.

18. The stacked semiconductor package of claim 17, wherein
the heat source mark includes an adhesive layer between the first semiconductor package and the heat dissipation member, or
the heat source mark is configured as a portion of an outermost wiring layer of a redistribution portion included in the first semiconductor package.

19. A lower semiconductor package for a stacked semiconductor package, the lower semiconductor package comprising:
a semiconductor chip including a first element at a first region and a second element at a second region, the second element being a higher power element than the first element;
a first redistribution portion and a second redistribution portion respectively on opposite surfaces of the semiconductor chip;
a mold layer surrounding the semiconductor chip between the first redistribution portion and the second redistribution portion; and
a heat source mark at the second region to overlap at least a portion of the second element in a vertical direction at an outer surface of the second redistribution portion and configured as a bonding member, the vertical direction extending perpendicular to an in-plane direction of the lower semiconductor package.

20. The lower semiconductor package of claim 19, wherein
the first region is at one side of one direction of the lower semiconductor package and the second region is disposed at another side of the one direction of the lower semiconductor package,
the semiconductor chip further includes a through connecting portion that penetrates the mold layer at the first region to connect the first redistribution portion and the second redistribution portion, and
the semiconductor chip is shifted toward the other side of the one direction.
